(19) United States
(12) Patent Application Publication
(10) Pub. No.: US 2014/0034586 A1
(43) Pub. Date: Feb. 6, 2014

(54) System for Holding Multiple Remote Controls

(71) Applicant: Mark Cole Eaton, Austin, TX (US)

(72) Inventor: Mark Cole Eaton, Austin, TX (US)

(21) Appl. No.: 13/564,720

(22) Filed: Aug. 2, 2012

(51) Int. Cl. H05K 7/18

(52) U.S. Cl. 211/26.1

(57) ABSTRACT

An improved method for holding multiple remote controls described herein. In one embodiment, the remote control holder can comprise a tray having a top surface, one or more remote control grip, and a first fastener. In this embodiment, each of the remote control grips can have a base and at least two sides. The base can comprise a top surface and a bottom surface. Further, the first fastener connected to the bottom surface of the remote control grip.

### BACKGROUND

This disclosure relates to a system for holding multiple remote controls.

Today, many people enjoy the comfort of operating their appliances and/or entertainment system from a distance, through the help of remote controls. Often, a household can own two or more remote controls. But since remote controls are small, and easily carried, most of the time remote controls are misplaced and lost. A user could either search for the remote control, or go towards the device and operate it using the controls that are usually affixed on a remote-controlled device. However, searching for remote controls and/or other small handheld devices can be exhausting and time consuming. Furthermore, operating a remote controlled device by going towards it, can be very inconvenient and defeats the purpose of owning a remote controlled appliance. Additionally, several remote controls scattered on the table or around a living room can be very unsightly. It would therefore be advantageous to have an improved system for holding multiple remote controls.

### SUMMARY

An improved method for holding multiple remote controls described herein. In one embodiment, the remote control holder can comprise a tray having a top surface, one or more remote control grip, and a first fastener. In this embodiment, each of the remote control grips can have a base and at least two sides. The base can comprise a top surface and a bottom surface. Further, the first fastener connected to the bottom surface of the remote control grip.

In another embodiment, the remote control holder can comprise the tray, a remote plate connectable to a remote control, and a tray interface plate having a top surface and a bottom surface. The top surface connectable to the remote plate, and the bottom surface connectable to the tray.

Further, in another embodiment, the remote control holder can comprise the tray having one or more tracks, a spacer, and one or more lock. The spacer can comprise one or more guides, the guides connectable with the tracks. The lock that can prevent the spacer from leaving the tracks.

### BRIEF DESCRIPTION OF THE DRAWINGS

FIG. 1A illustrates an embodiment of remote control holder that uses a fastener method.

FIG. 1B illustrates a tray comprising a fastener, a first strip.

FIG. 1C illustrates a remote control holder comprising a fastener, a second strip.

FIG. 2A illustrates another embodiment of a remote control holder that uses a slide-lock mechanism.

FIG. 2B illustrates a remote plate of a remote control holder.

FIG. 2C illustrates a tray interface plate of a remote control holder.

FIG. 2D illustrates an embodiment of a tray of a remote control holder.

FIG. 3A illustrates an embodiment of remote control holder that uses a track and guide method.

FIG. 3B illustrates a tray comprising one or more tracks.

FIG. 3C illustrates a side view of tracks.

FIG. 3D illustrates a spacer.

FIG. 3E illustrates an embodiment of lock comprising one or more vises and one or more washers.

### DETAILED DESCRIPTION

Described herein is a system for holding multiple remote controls. The following description is presented to enable any person skilled in the art to make and use the invention as claimed and is provided in the context of the particular examples discussed below, variations of which will be readily apparent to those skilled in the art. In the interest of clarity, not all features of an actual implementation are described in this specification. It will be appreciated that in the development of any such actual implementation (as in any development project), design decisions must be made to achieve the designers' specific goals (e.g., compliance with system- and business-related constraints), and that these goals will vary from one implementation to another. It will also be appreciated that such development effort might be complex and time-consuming, but would nevertheless be a routine undertaking for those of ordinary skill in the field of the appropriate art having the benefit of this disclosure. Accordingly, the claims appended hereto are not intended to be limited by the disclosed embodiments, but are to be accorded their widest scope consistent with the principles and features disclosed herein.

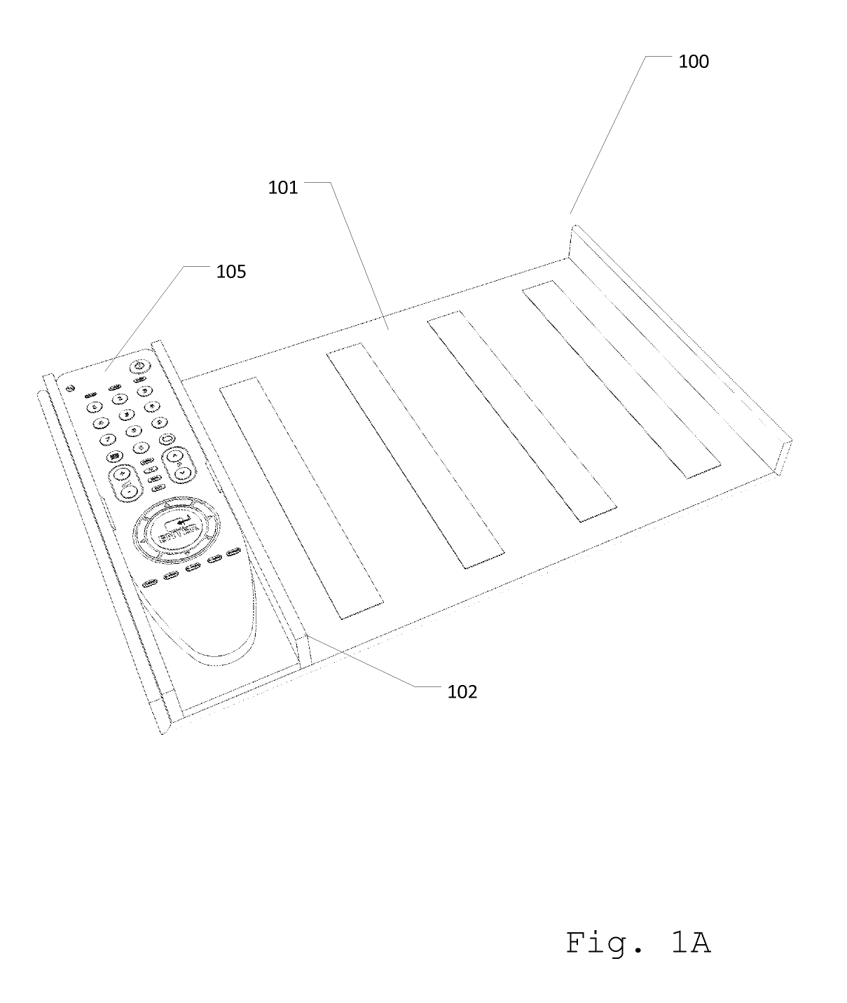

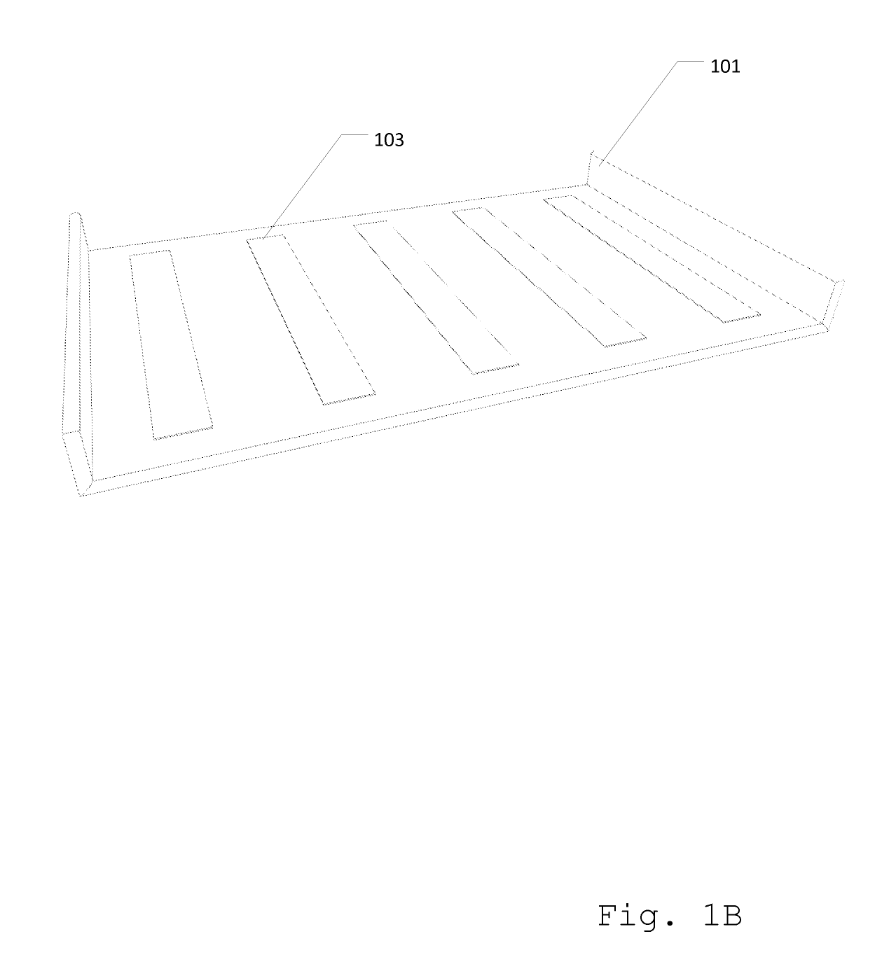

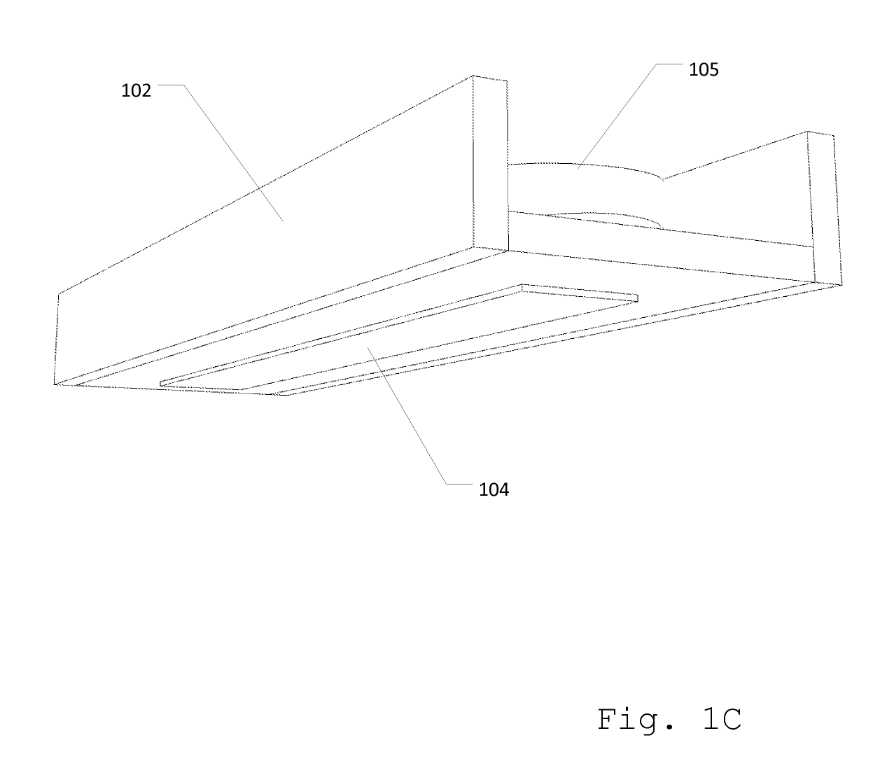

FIG. 1A illustrates an embodiment of a remote control holder 100 that uses a fastener method. Fastener method can include any type of snap, button, or hook and loop system. Remote control holder 100 can comprise a tray 101, and a remote control grip 102. Remote control grip 102 can be made of any material, which includes but is not limited to wood, metal, plastic, rubber, and/or fabric. Remote control holder 100 can be any material that can be used to attach a remote control 105 to tray 101. Further, remote control holder 100 can either be permanently or temporarily attached to remote control 105.

FIG. 1B illustrates tray 101 comprising a fastener—in this figures, a first strip 103. In one embodiment, first strip 103 can be a hook from a hook-and-loop fastener. One or more first strip 103 can be permanently attached to tray 101. First strips 103 can be placed at the top surface of tray 101 through sewing, or any adhesives.

FIG. 1C illustrates remote control holder 100 comprising a fastener—in this figure, a second strip 104. In one embodiment, second strip 104 can be a loop from a hook-and-loop fastener. One or more second strip 104 can be permanently attached at the bottom of remote control holder 100 through sewing, or any adhesives. As such, second strip 104 of remote control holder 100 can be fastened to first strips 103 of tray 101. In another embodiment, second strip 104 can be a magnet that attaches remote casing to tray 101 comprising ferromagnetic material.

In one embodiment, remote control holder 100 can be made of a material, which includes but is not limited to thin sheet of metal, and/or plastics. In such embodiment, remote control holder 100 can be designed to have a tray form. Thus, remote control holder 100 can serve as a container for remote control 105. Further, in such embodiment remote control holder 100 can be designed to have different sizes and/or dimension to fit variety of remote controls 105. In another embodiment, remote control holder 100 and second strip 104 can be considered as single device. In such embodiment, remote control holder 100 can be a thin piece of material permanently attached at the bottom surface of remote control 105 through any type of adhesives. In one embodiment wherein fastener can use hook and loop system, first strip 103 can cover substantially the entire surface of tray 101. In such embodiment, remote control holder 100 comprising second strip 104 can be mateable with tray 101 in many places on tray 101.

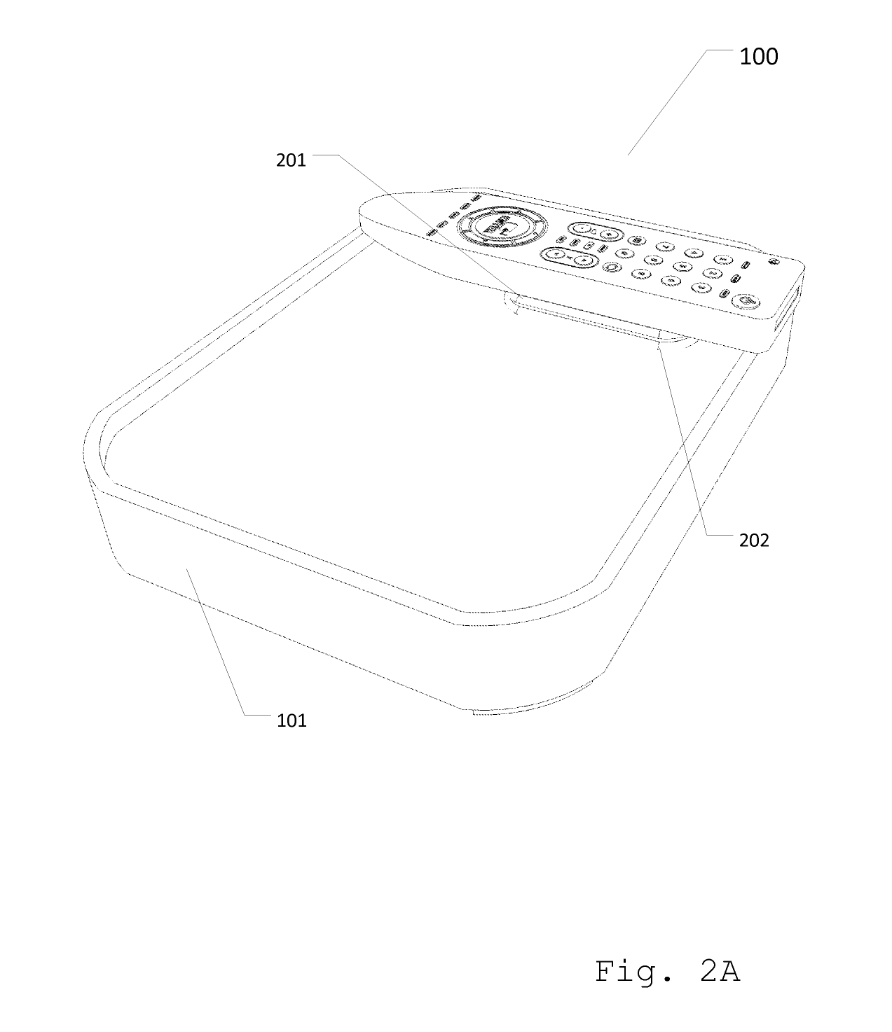

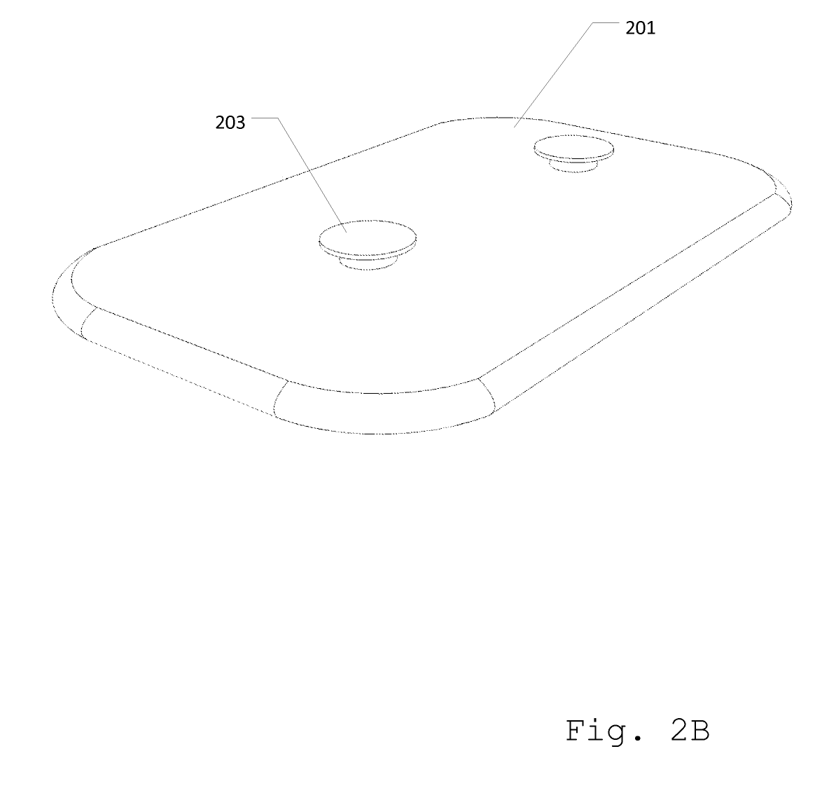

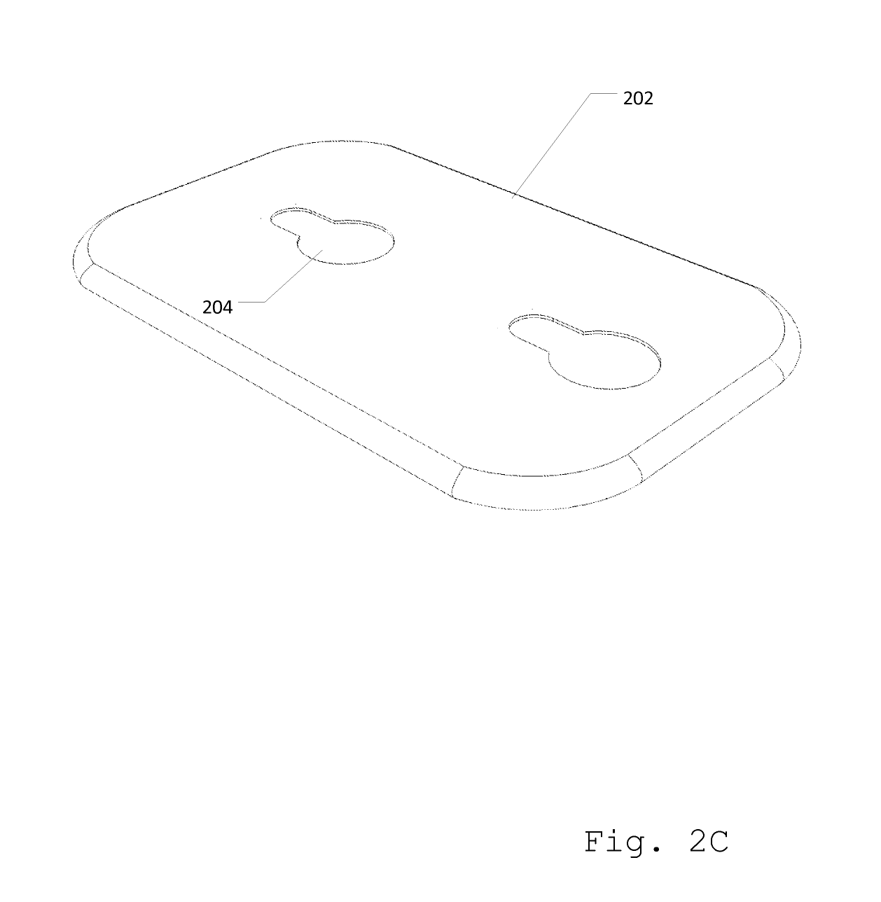

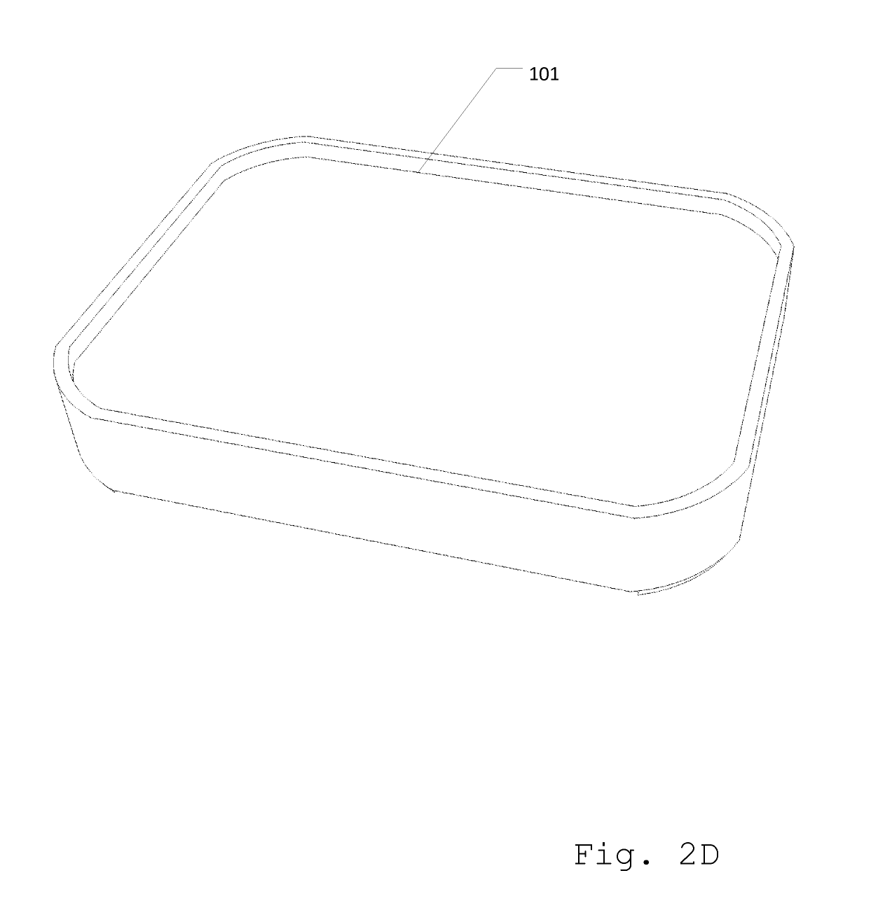

FIG. 2A illustrates another embodiment of remote control holder 100 that uses a slide-lock mechanism. Slide-lock mechanism can be a mechanical fastening method of joining two objects together. Slide-lock mechanism can comprise a remote plate 201 and a tray interface plate 202. As such, joined objects can be fastened and unfastened repeatedly. In such embodiment, remote control holder 100 can comprise of remote plate 201 mounted to the top surface of tray interface plate 202, and tray 101.

FIG. 2B illustrates remote plate 201 of remote control holder 100. Remote plate 201 can be made of, but is not limited to, metal, silicone, rubber, and/or plastics. Further, remote plate 201 can comprise of one or more catches 203. Catches 203 can be defined by a thin portion that attaches a head to the remote plate 201. Remote control 105 can be attached to remote plate 201 through any adhesive material.

FIG. 2C illustrates tray interface plate 202 of remote control holder 100. Tray interface plate 202 can be made of materials, which can include but are not limited to metal, silicone, rubber, and/or plastics. Further, tray interface plate 202 can comprise of one or more holes 204. One or more holes 204 can have a catch-hold portion, and a catch-release portion. At the catch-release portion, catch 203 can slip inside hole 204. Upon sliding down into catch-hold portion, catch 203 can no longer come out of hole 204. In one embodiment, tray interface plate 202 can be hollow so as to allow a space for the head of catch 203 to reside. Tray interface plate 202 can be attached to tray 101 in any of the ways including, but not limited to, snaps, buttons, hook and loop fasteners, or magnets. In one embodiment, remote plate 201 can comprise holes 204 and tray interface plate 202 can comprise catches 203.

FIG. 2D illustrates an embodiment of tray 101 of remote control holder 100. Tray 101 can be made of a sturdy material that includes but are not limited to wood, metal, plastic, and/or rubber. In one embodiment tray interface plate 202 can be attached to tray 101 and can be considered as one device. As such, tray 101 can comprise holes 204. In another embodiment, tray interface plate 202 can attach to tray 101, and in some embodiments, can be detachable. In such embodiment, flat surface of tray interface plate 202 can attach to tray 101 using hook and loop fasteners, snaps, glue, or other adhesives.

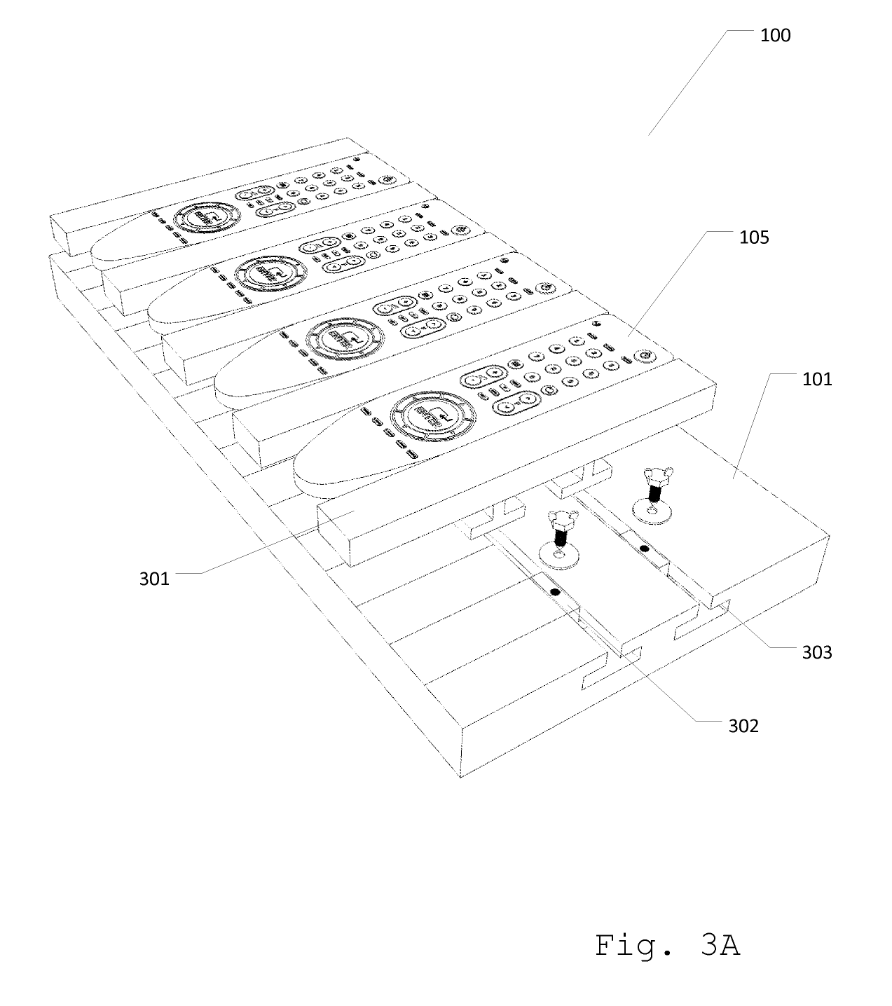

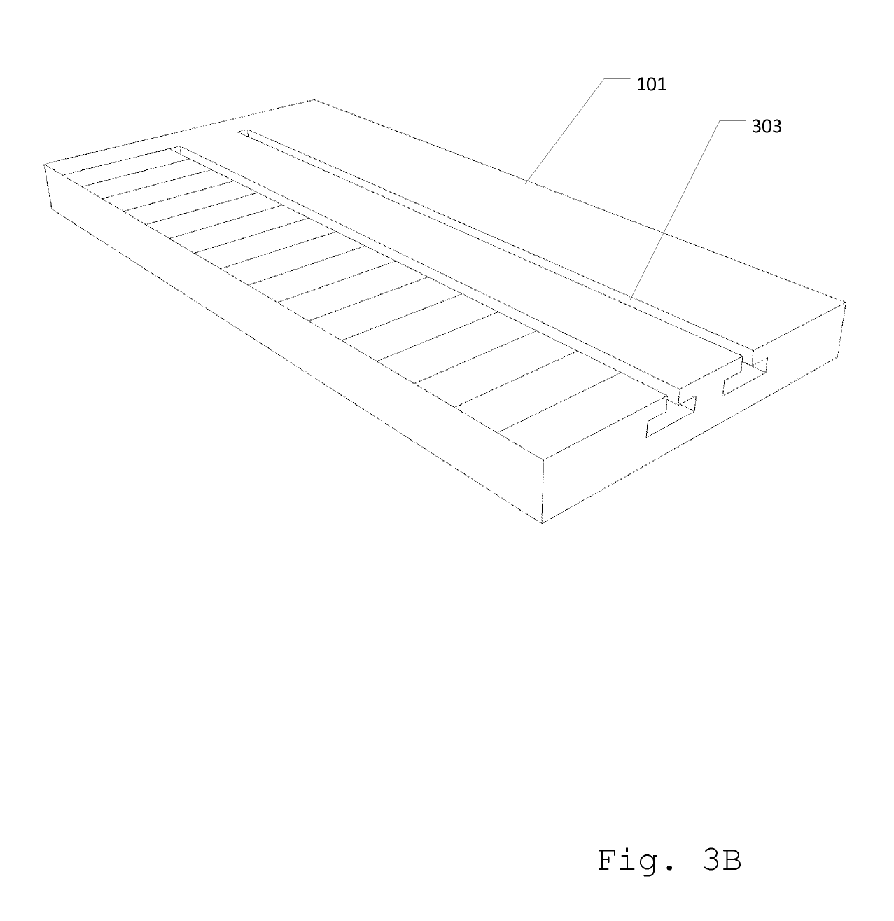

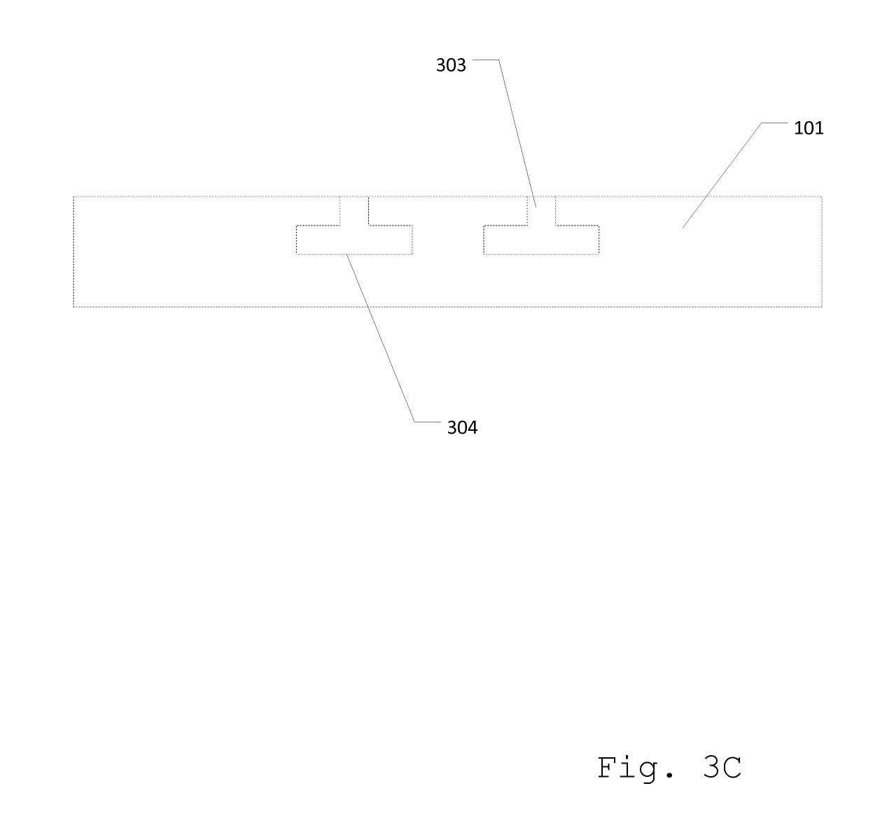

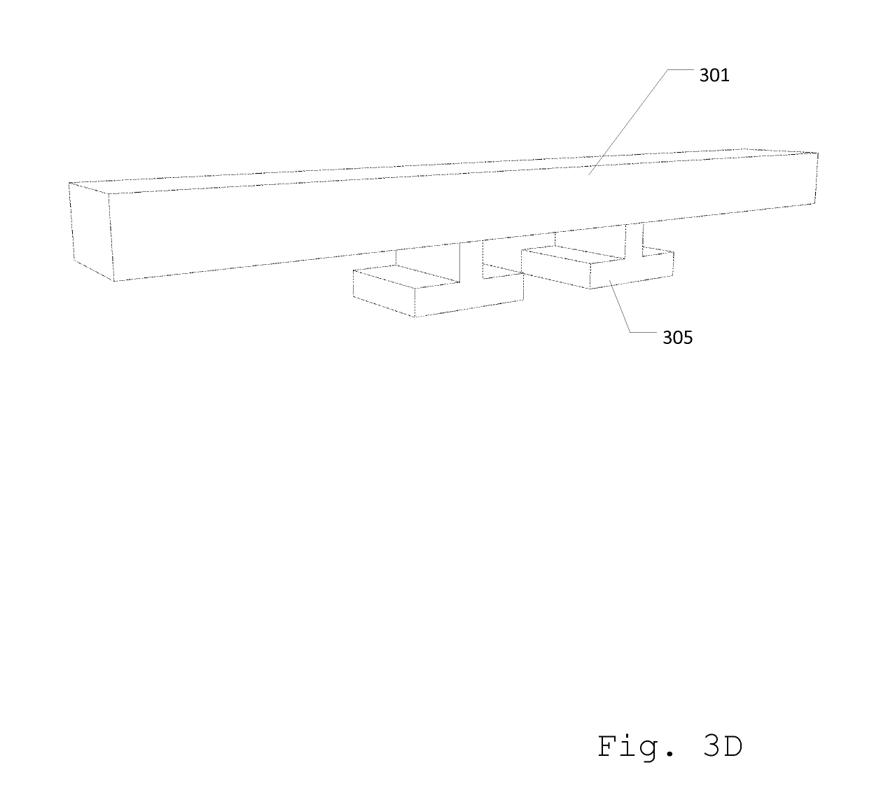

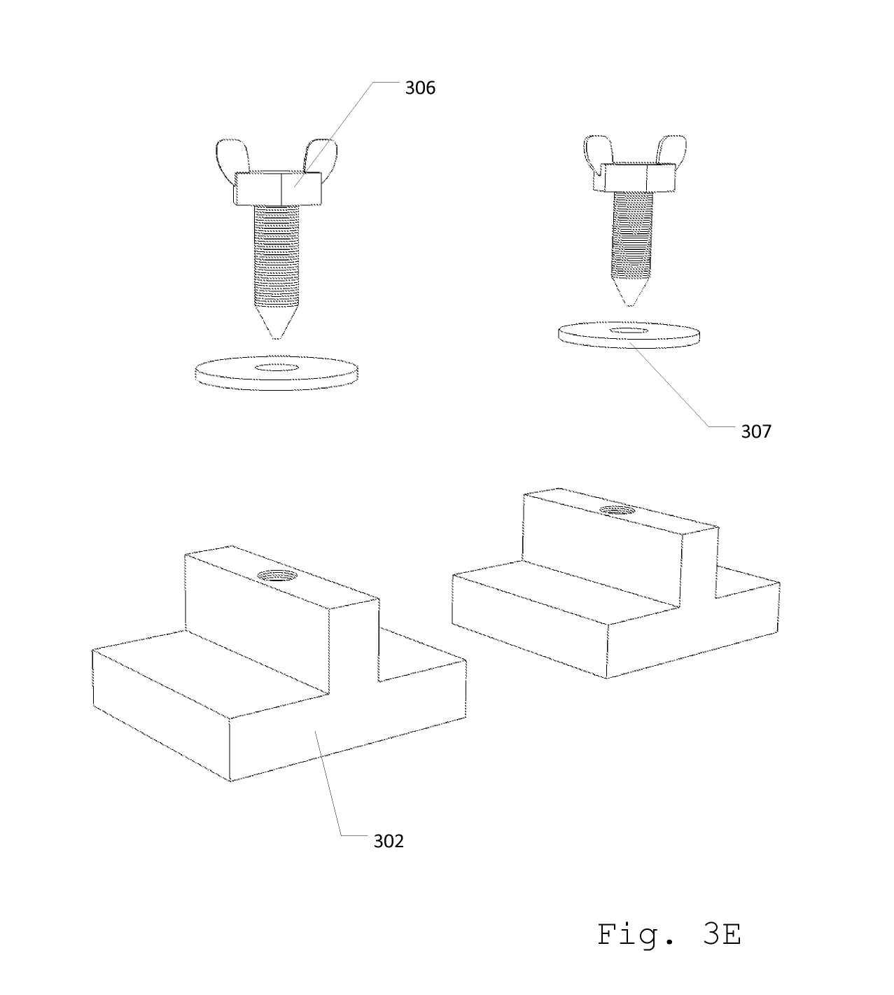

FIG. 3A illustrates an embodiment of remote control holder 100 that uses a track and guide method. In such embodiment, remote control holder 100 can comprise tray 101, one or more spacers 301, and a lock 302. Spacer 301 can be an elongated bar material that separates remote controls 105. Spacer 301 can be made of any material that includes but are not limited to wood, metal, plastic, rubber, and/or fabric. Lock 302 can be made of durable material in a shape mateable with track 303. Lock 302 can be used hold remote controls 105 and spacers 301 in place.

FIG. 3B illustrates tray 101 comprising one or more tracks 303. In embodiment, tracks 303 can be a pair of depressed portion at the top surface of tray 101. Tracks 303 parallel to each other and run along tray 101. Further, track 303 can be t-shape or 1-shape in form, wherein the narrow portion of track 303 can serve as small opening on the surface of tray 101 further widening near the bottom of tray 101.

FIG. 3C illustrates a side view of tracks 303. Track 303 can form a t-shape opening 304 at one side of tray 101. In one embodiment, T-shape opening 304 can go all the way through the other side of tray 101. In another embodiment, track 303 can terminate before the end of tray 101. In such embodiment, the end of the tray 101 provides a stopping point for a first spacer 301. After the first spacer 301 is in place, a first remote control can be placed on tray 101.

FIG. 3D illustrates spacer 301. Spacer 301 can comprise a guide 305 that connects spacer 301 to track 303. Guide 305 can be inserted at opening 304 and be pushed to the other side of tray 101. As such, spacer 301 can glide through tracks 303 directing spacer 301 to the edge of tray 101. Remote control 105 can then be placed after first guide 305 has been pushed on one end of the board. After positioning remote control 105 in place, a second guide 305 can be inserted again at t-shape opening 304. Second guide 305 can be pushed towards remote control 105 pressing it tightly against first guide 305. This process can be repeated to place multiple remote controls 105 in place.

FIG. 3E illustrates an embodiment of lock 302 comprising one or more vises 306 and one or more washers 307. Lock 302 can then be inserted into t-shape opening 304 and be pushed towards guide 305. Vise 306 can be a mechanical screw apparatus that can be used to hold or secure lock 302 in a desired position. Vise 306 can be attached at the top surface of lock 302. Washers 307 can be a thin plate comprising a hole in the middle wherein vise 306 can be inserted. Vise 306 can then be tightened or screwed unto lock 302 to tighten lock 302 in place and ensure that guides 305 and remote controls 105 are tightly clasped together. As such, vise 306 can transfer the force and/or load to washer 307. Further, vise 306 and washer 307 can be screwed into lock 302 that can tighten and push lock 302 in place. Unscrewing vise 306 can loosen lock 302, allowing lock 302 to be moved along track 303.

Various changes in the details of the illustrated operational methods are possible without departing from the scope of the following claims. Some embodiments may combine the activities described herein as being separate steps. Similarly, one or more of the described steps may be omitted, depending upon the specific operational environment the method is being implemented in. It is to be understood that the above description is intended to be illustrative, and not restrictive. For example, the above-described embodiments may be used in combination with each other. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.”

1. A remote control holder comprising
a tray having a top surface;
one or more remote control grip, each of said remote control grip having a base and at least two sides, said base comprising a top surface and a bottom surface;
a first fastener connected to the bottom surface of said remote control grip.

2. The remote control holder of claim 1 wherein
said tray is ferromagnetic; and
said first fastener is a magnet.

3. The remote control holder of claim 1 further comprising a second fastener connected to said tray.

4. The remote control holder of claim 3 wherein said first fastener and said second fastener are hook and loop fasteners.

5. The remote control holder of claim 1 wherein said remote control grip comprises rubber.

6. The remote control holder of claim 1 wherein said remote control grip comprises plastic.

7. A remote control holder comprising
a tray;
a remote plate connectable to a remote control; and
a tray interface plate having a top surface and a bottom surface, said top surface connectable to said remote plate, and said bottom surface connectable to said tray.

8. The remote control holder of claim 7 wherein said remote plate comprises one or more catches, further wherein said top surface of said tray interface plate comprises one or more holes.

9. The remote control holder of claim 7 wherein said top surface of said tray interface plate comprises one or more catches, further wherein said remote plate comprises one or more holes.

10. The remote control holder of claim 7 further comprising hook and loop fasteners that connect said tray interface plate to said top of said tray.

11. A remote control holder comprising
a tray comprising one or more tracks;
a spacer comprising one or more guides, said guides connectable with said tracks; and
a one or more lock that prevents said spacer from leaving said tracks.

12. The remote control holder of claim 11 wherein each of said lock can comprise a vice.

13. The remote control holder of claim 11 wherein said lock can comprise a latch.
